(19) United States
(12) Patent Application Publication
(10) Pub. No.: US 2025/0311343 A1
(43) Pub. Date: Oct. 2, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Hideki SAKURAI, Himeji (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/826,400

(22) Filed: Sep. 6, 2024

(30) Foreign Application Priority Data
Apr. 2, 2024 (JP) 2024-059666

(51) Int. Cl. H01L 29/267; H01L 29/36; H01L 29/778

(52) U.S. Cl. CPC H10D 62/82; H10D 30/475; H10D 62/60

(57) ABSTRACT

According to one embodiment, a semiconductor device includes a first semiconductor layer, a second semiconductor layer, a first electrode, a second electrode, a gate electrode, and a third semiconductor layer. The first semiconductor layer contains Alₓ₁Ga₁₋ₓ₁N (0≤x1<1). The second semiconductor layer is provided on the first semiconductor layer and contains Alₓ₂Ga₁₋ₓ₂N (0<x2<1, x1<x2). The second semiconductor layer includes a first portion and a second portion. The second portion is separated from the first portion. The first electrode is provided on the first portion. The second electrode is provided on the second portion. The gate electrode is provided between the first electrode and the second electrode. The third semiconductor layer is located between the gate electrode and the second electrode and contains carbon and gallium nitride. A concentration of carbon in the third semiconductor layer is greater than 5.0×10¹⁷ cm⁻³.

### CROSS-REFERENCE TO RELATED APPLICATIONS

This application is based upon and claims the benefit of priority from Japanese Patent Application No. 2024-059666, filed on Apr. 2, 2024; the entire contents of which are incorporated herein by reference.

### FIELD

Embodiments of the present invention generally relating to a semiconductor device.

### BACKGROUND

There are semiconductor devices containing gallium nitride. For these semiconductor devices, there is a need for technology that can suppress the occurrence of current collapse.

### BRIEF DESCRIPTION OF THE DRAWINGS

FIG. 1 is a cross-sectional view illustrating a semiconductor device according to an embodiment;

FIGS. 2A and 2B are cross-sectional views illustrating the manufacturing method for the semiconductor device according to the embodiment;

FIGS. 3A and 3B are cross-sectional views illustrating the manufacturing method for the semiconductor device according to the embodiment;

FIG. 4 is a schematic view illustrating a structure of a third semiconductor layer;

FIG. 5 is a cross-sectional view illustrating a semiconductor device according to a first modification of the embodiment;

FIG. 6 is a cross-sectional view illustrating a semiconductor device according to a second modification of the embodiment;

FIG. 7 is a cross-sectional view illustrating a semiconductor device according to a third modification of the embodiment; and

FIG. 8 is a cross-sectional view illustrating a semiconductor device according to a fourth modification of the embodiment.

### DETAILED DESCRIPTION

According to one embodiment, a semiconductor device includes a first semiconductor layer, a second semiconductor layer, a first electrode, a second electrode, a gate electrode, and a third semiconductor layer. The first semiconductor layer contains Alₓ₁Ga₁₋ₓ₁N (0≤x1<1). The second semiconductor layer is provided on the first semiconductor layer and contains Alₓ₂Ga₁₋ₓ₂N (0<x2<1, x1<x2). The second semiconductor layer includes a first portion and a second portion. The second portion is separated from the first portion in a second direction perpendicular to a first direction from the first semiconductor layer toward the second semiconductor layer. The first electrode is provided on the first portion. The second electrode is provided on the second portion. The gate electrode is provided between the first electrode and the second electrode. The third semiconductor layer is located between the gate electrode and the second electrode and contains carbon and gallium nitride. A concentration of carbon in the third semiconductor layer is greater than 5.0×10¹⁷ cm⁻³.

Various embodiments will be described hereinafter with reference to the accompanying drawings. The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions. In the specification and drawings, components similar to those described or illustrated in a drawing therein above are marked with like reference numerals, and a detailed description is omitted as appropriate.

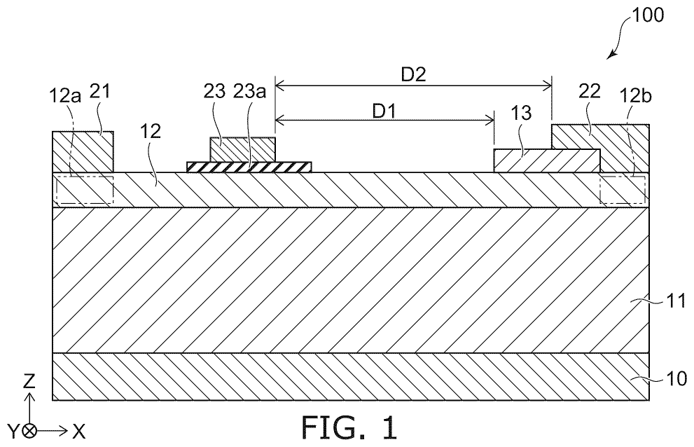

FIG. 1 is a cross-sectional view illustrating a semiconductor device according to an embodiment.

As shown in FIG. 1, the semiconductor device 100 according to the embodiment includes a semiconductor substrate 10, a first semiconductor layer 11, a second semiconductor layer 12, a third semiconductor layer 13, a source electrode 21 (a first electrode), a drain electrode 22 (a second electrode), and a gate electrode 23.

In the description of the embodiment, an XYZ Cartesian coordinate system is used. The direction from the first semiconductor layer 11 toward the second semiconductor layer 12 is taken as Z-direction (a first direction). The two directions perpendicular to the Z-direction and perpendicular to each other are taken as X-direction (a second direction) and Y-direction. For the sake of explanation, the direction from the first semiconductor layer 11 toward the second semiconductor layer 12 is called “up/above”, and the opposite direction is called “below”. These directions are based on the relative positional relationship between the first semiconductor layer 11 and the second semiconductor layer 12, and are independent of the direction of gravity.

The first semiconductor layer 11 is provided on the semiconductor substrate 10 and contains Alₓ₁Ga₁₋ₓ₁N (0≤x1<1). The semiconductor substrate 10 is, for example, a Si substrate. A buffer layer (not shown) may be provided between the semiconductor substrate 10 and the first semiconductor layer 11. The second semiconductor layer 12 is provided on the first semiconductor layer 11 and contains Alₓ₂Ga₁₋ₓ₂N (0<x2<1, x1<x2). As an example, the first semiconductor layer 11 is a GaN layer that substantially does not contain Al, and the second semiconductor layer 12 is an AlGaN layer.

The second semiconductor layer 12 includes a first portion 12a and a second portion 12b. The first portion 12a and the second portion 12b are separated from each other in the X-direction. The source electrode 21 is provided on the first portion 12a. The drain electrode 22 is provided on the second portion 12b. The source electrode 21 and the drain electrode 22 are electrically connected to the second semiconductor layer 12. The source electrode 21 and the drain electrode 22 are separated from each other in the X-direction.

The gate electrode 23 is provided on the second semiconductor layer 12 with a gate insulating layer 23a interposed, and is located between the source electrode 21 and the drain electrode 22 in the X-direction. The gate electrode 23 is separated from the source electrode 21 and the drain electrode 22. For example, the distance between the drain electrode 22 and the gate electrode 23 is longer than the distance between the source electrode 21 and the gate electrode 23. The source electrode 21, drain electrode 22, and gate electrode 23 include a metal material such as titanium, copper, or aluminum.

The third semiconductor layer 13 is provided on the second semiconductor layer 12 and is located between the drain electrode 22 and the gate electrode 23 in the X-direction. The third semiconductor layer 13 contains carbon and gallium nitride. For example, the third semiconductor layer 13 is separated from the gate electrode 23 and is in contact with the drain electrode 22. A part of the drain electrode 22 is provided on the third semiconductor layer 13.

The operation of the semiconductor device 100 will be described. The semiconductor device 100 is a normally-on type device. At the interface between the first semiconductor layer 11 and the second semiconductor layer 12, two-dimensional electron gas (2DEG) is generated. When a positive voltage is applied to the drain electrode 22 with respect to the source electrode 21, the electrons contained in the two-dimensional electron gas move from the source electrode 21 to the drain electrode 22. Thereby, a current flows between the source electrode 21 and the drain electrode 22. When a negative voltage is applied to the gate electrode 23, electrons in the region directly below the gate electrode 23 are repelled, and the region is depleted. As a result, the semiconductor device 100 is turned off.

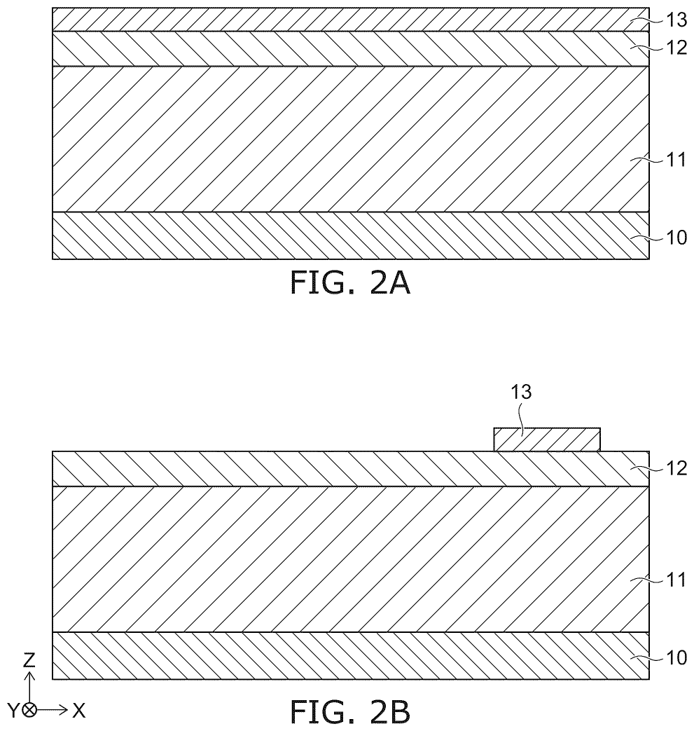

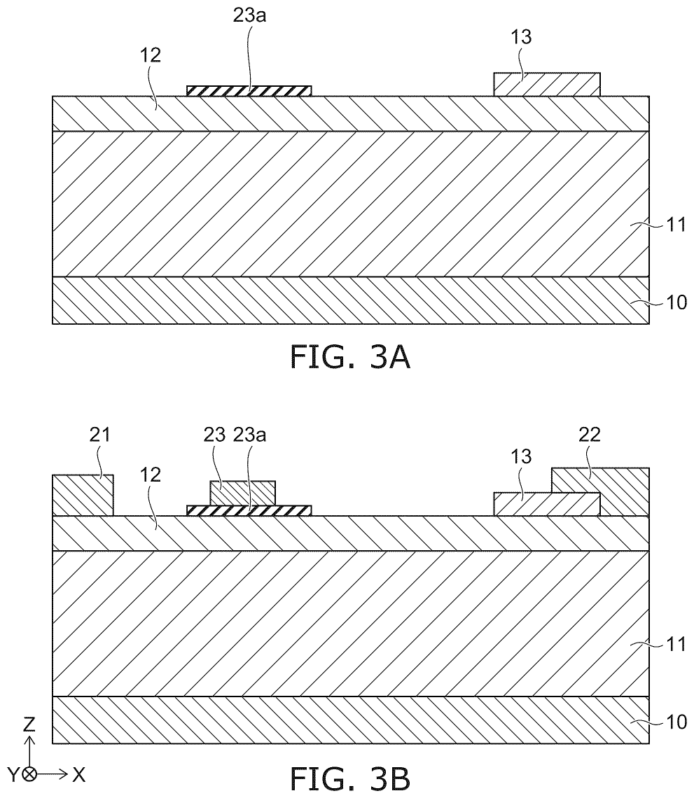

FIGS. 2A, 2B, 3A, and 3B are cross-sectional views illustrating the manufacturing method for the semiconductor device according to the embodiment.

First, the semiconductor substrate 10 is prepared. As shown in FIG. 2A, the first semiconductor layer 11, the second semiconductor layer 12, and the third semiconductor layer 13 are sequentially formed on the semiconductor substrate 10 by metal-organic chemical vapor deposition (MOCVD). When forming the third semiconductor layer 13, carbon is added. A part of the third semiconductor layer 13 is removed by reactive ion etching (RIE). As a result, as shown in FIG. 2B, a part of the upper surface of the second semiconductor layer 12 is exposed.

A gate insulating layer 23a is formed on the exposed upper surface of the second semiconductor layer 12 by chemical vapor deposition (CVD). As shown in FIG. 3A, a part of the gate insulating layer 23a is removed by RIE. As shown in FIG. 3B, the gate electrode 23 is formed at a position away from the third 10 semiconductor layer 13, and the source electrode 21 and the drain electrode 22 are formed on the exposed upper surface of the second semiconductor layer 12. A part of the drain electrode 22 is also formed on the third semiconductor layer 13. By the above steps, the semiconductor device 100 according to the embodiment is manufactured.

The advantages of the embodiment will be described.

Current collapse in semiconductor devices is caused by crystal defects in the semiconductor layer, trapping of electrons at the interface of the semiconductor layer, etc. In the embodiment of the present invention, the semiconductor device 100 includes the third semiconductor layer 13 in order to suppress the occurrence of current collapse. The third semiconductor layer 13 contains carbon and gallium nitride, and the carbon concentration is greater than 5.0×10¹⁷ cm⁻³.

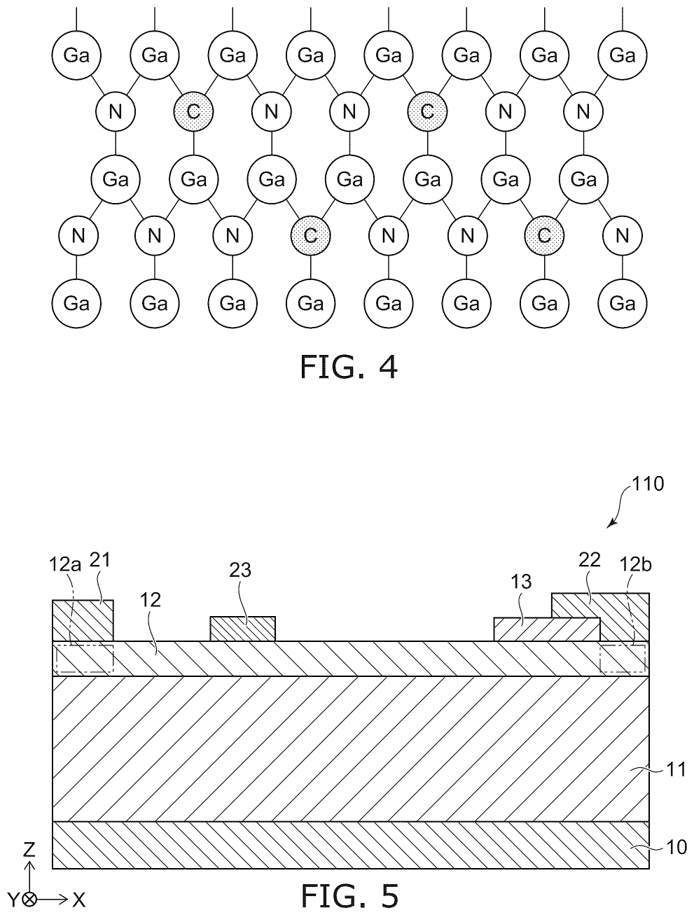

FIG. 4 is a schematic view illustrating the structure of the third semiconductor layer.

As shown in FIG. 4, the majority of the third semiconductor layer 13 has a crystal structure of gallium and nitrogen. And some of the nitrogen is replaced by carbon. Nitrogen is an element of group V, and carbon is an element of group IV. When nitrogen is replaced by carbon, carbon functions as an acceptor in the third semiconductor layer 13. In other words, the third semiconductor layer 13 functions as a p-type semiconductor layer. From the third semiconductor layer 13, holes are supplied to the interface between the second semiconductor layer 12 and the third semiconductor layer 13. By supplying the holes, the electrons trapped at the interface between the second semiconductor layer 12 and the third semiconductor layer 13 are neutralized. As a result, current collapse in the semiconductor device 100 is suppressed. In particular, by increasing the carbon concentration to greater than 5.0×10¹⁷ cm⁻³, a sufficient amount of holes are supplied from the third semiconductor layer 13 to the interface between the second semiconductor layer 12 and the third semiconductor layer 13, and current collapse can be preferably suppressed.

Other than carbon, calcium, zinc, beryllium, magnesium, etc. may be applicable as acceptors for gallium nitride. However, calcium, zinc, and beryllium are considered more difficult to activate as p-type impurities compared to carbon. When magnesium is used, a large amount of hydrogen is incorporated into the semiconductor layer along with magnesium. Thus, a process for desorbing hydrogen from the semiconductor layer is required. The incorporation of a large amount of hydrogen may also affect the reliability of the semiconductor device. Therefore, carbon is more preferable to elements such as calcium, zinc, beryllium, and magnesium.

When carbon is incorporated into the third semiconductor layer 13 as an acceptor, in the formation of the third semiconductor layer 13, carbon can be added to the film by an autodoping method or an external doping method during gallium nitride crystal growth. The autodoping method uses carbon derived from the organometallic gas used as the raw material. There is a technical problem that is constrained by growth conditions because it is necessary to control the amount of carbon added according to the growth temperature and growth rate. On the other hand, adding carbon by external doping using dopant gases such as acetylene (C₂H₂) increases the flexibility of the growth temperature or growth rate in the epitaxial process parameters. Therefore, it is preferable for carbon addition to use the external doping. For more detailed methods, for example, are discussed in Xun Li et al., “Precursors for carbon doping of GaN in chemical vapor deposition”, Journal of Vacuum Science & Technology B, 2015, vol. 33. No. 2. Alternatively, Yoshio Honda et al., “DAP emission band in a carbon doped (1-101) GaN grown on (001) Si substrate”, physica status solidi c, 2009, Vol. S2, pp. S772 to S775 can be referenced.

The upper limit of the carbon concentration in the third semiconductor layer 13 is not particularly limited, but is preferably less than 1.0×10²⁰ cm⁻³. When the carbon concentration is 1.0×10²⁰ cm⁻³ or more, it exceeds the solid solubility limit of the carbon concentration in the gallium nitride layer, and crystal defects such as dislocations or surface pits appear. As a result, deterioration of the characteristics of the device such as current leakage may occur. Therefore, from the viewpoint of ensuring crystal quality and device characteristics, the carbon concentration in the third semiconductor layer 13 is preferably greater than 5.0×10¹⁷ cm⁻³ and less than 1.0×10²⁰ cm⁻³. More preferably, the carbon concentration in the third semiconductor layer 13 is not less than 1.0×10¹⁸ cm⁻³ and less than 1.0×10²⁰ cm⁻³.

The carbon concentration in the first semiconductor layer 11 and the carbon concentration in the second semiconductor layer 12 are preferably lower than that in the third semiconductor layer 13. For example, the carbon concentration in the first semiconductor layer 11 and the carbon concentration in the second semiconductor layer 12 are preferably not more than 5.0×10¹⁷ cm⁻³. More preferably, the carbon concentration in the first semiconductor layer 11 is not less than 1.0×10¹⁶ cm⁻³ and not more than 3.0×10¹⁶ cm⁻³, and the carbon concentration in the second semiconductor layer 12 is not less than 1.0×10¹⁵ cm⁻³ and not more than 1.0×10¹⁷ cm⁻³.

The third semiconductor layer 13 is preferably separated from the gate electrode 23. When the third semiconductor layer 13 is in contact with the gate electrode 23, carriers generated in the third semiconductor layer 13 causes electrical conduction between the gate electrode 23 and the drain electrode 22. Therefore, electrical separation is required. For example, the distance D1 between the gate electrode 23 and the third semiconductor layer 13 is not less than 0.5 times the distance D2 between the gate electrode 23 and the drain electrode 22. More preferably, the distance D1 is not less than 0.6 times the distance D2, and most preferably, the distance D1 is not less than 0.8 times the distance D2.

### First Modification

FIG. 5 is a cross-sectional view illustrating a semiconductor device according to a first modification of the embodiment.

The semiconductor device 110 shown in FIG. 5 differs from the semiconductor device 100 in that the gate electrode 23 is in contact with the second semiconductor layer 12. The gate electrode 23 includes a metal having a high work function, and a Schottky junction is formed between the second semiconductor layer 12 and the gate electrode 23. For example, the gate electrode 23 includes one or more selected from the group consisting of Ni, Au, Pd, V, and Pt. According to the semiconductor device 110, since the second semiconductor layer 12 is in contact with the gate electrode 23, the width of the depletion layer formed in the region of the first semiconductor layer 11 and the second semiconductor layer 12 directly below the gate electrode 23 can be controlled by the gate voltage. This allows the semiconductor device 110 to achieve a gate function.

### Second Modification

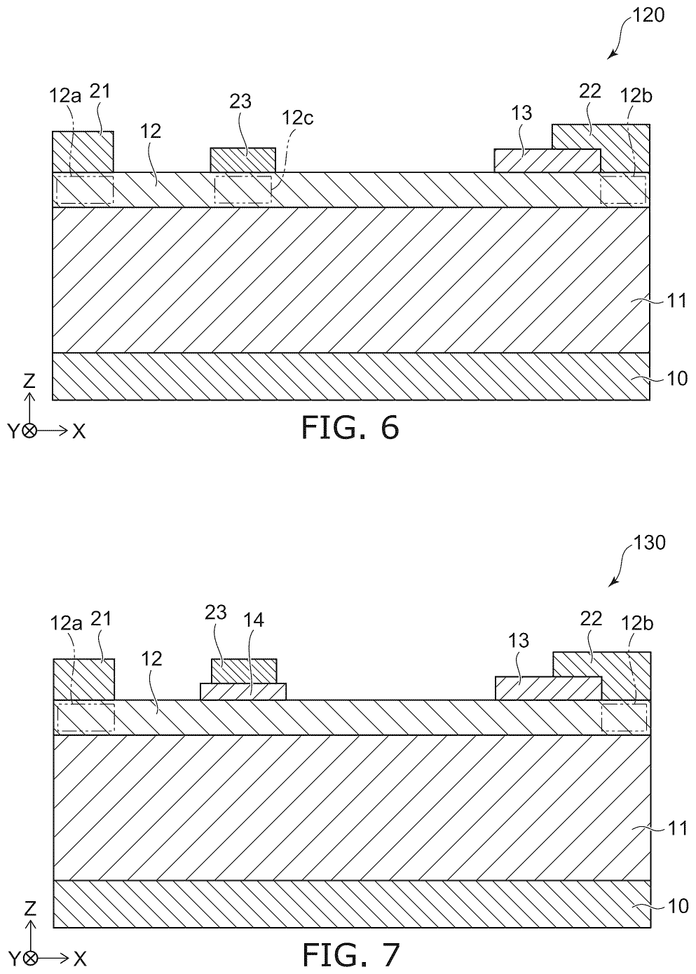

FIG. 6 is a cross-sectional view illustrating a semiconductor device according to a second modification of the embodiment.

In the semiconductor device 120 shown in FIG. 6, the second semiconductor layer 12 includes a third portion 12c located between the first portion 12a and the second portion 12b. The fluorine concentration in the third portion 12c is greater than the fluorine concentration in the first portion 12a and greater than the fluorine concentration in the second portion 12b. The gate electrode 23 is provided on the third portion 12c and is in contact with the third portion 12c.

The third portion 12c is formed, after forming the first semiconductor layer 11, the second semiconductor layer 12, and the third semiconductor layer 13, by removing a part of the third semiconductor layer using etching and then injecting fluorine ions or irradiating fluorine plasma onto a part of the second semiconductor layer 12 (the third portion 12c).

The fluorine concentration in the third portion 12c is preferably 1.0×1019 (atm/cm 3) or more. The fluorine concentration in the third portion 12c is preferably not less than 40 times and not more than 2000 times the fluorine concentration (atm/cm³) in the first portion 12a or the second portion 12b.

According to the semiconductor device 120, by providing the third portion 12c with a high fluorine concentration in the second semiconductor layer 12, the gate current is suppressed and the controllability of the threshold voltage is improved.

### Third Modification

FIG. 7 is a cross-sectional view illustrating a semiconductor device according to a third modification of the embodiment.

The semiconductor device 130 shown in FIG. 7 differs from the semiconductor device 100 in that a fourth semiconductor layer 14 is provided between the second semiconductor layer 12 and the gate electrode 23. The fourth semiconductor layer 14 is a p-type semiconductor layer and is in contact with the second semiconductor layer 12 and the gate electrode 23. The fourth semiconductor layer 14 is separated from the third semiconductor layer 13 and the source electrode 21 in the X-direction. The fourth semiconductor layer 14 contains one or more selected from the group consisting of carbon and magnesium as a p-type impurity.

By providing the fourth semiconductor layer 14, the region directly below the gate electrode 23 in the second semiconductor layer 12 is depleted in a state where no voltage is applied to the gate electrode 23. When a voltage exceeding the threshold value is applied to the gate electrode 23, holes are injected into the region directly below the gate electrode 23, and the semiconductor device 130 is turned on. In other words, the semiconductor device 130 is a normally-off type device.

### Fourth Modification

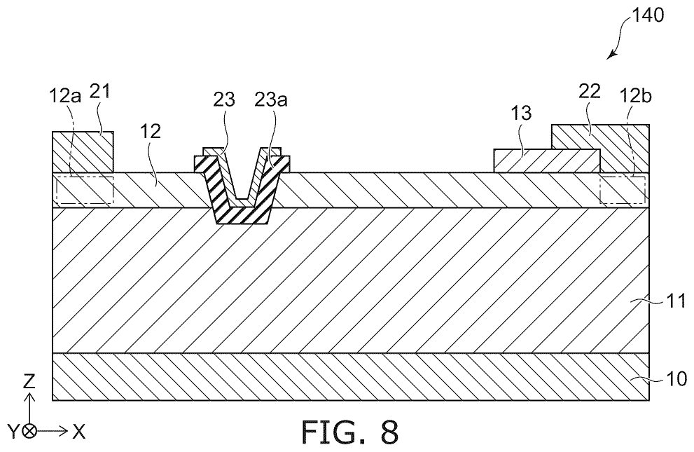

FIG. 8 is a cross-sectional view illustrating a semiconductor device according to a fourth modification of the embodiment.

The semiconductor device 140 shown in FIG. 8 differs from the semiconductor device 100 in that the gate electrode 23 is located between the first portion 12a and the second portion 12b. The gate electrode 23 faces the first semiconductor layer 11 in the Z-direction with the gate insulating layer 23a interposed. The gate electrode 23 faces the second semiconductor layer 12 in the X-direction with the gate insulating layer 23a interposed. The semiconductor device 140 has a recess gate structure.

In the semiconductor device 140, the 2DEG generated in the region directly below the source electrode 21 and the 2DEG generated in the region directly below the drain electrode 22 are separated by the gate insulating layer 23a. For this reason, the semiconductor device 140 is a normally-off type device. When a voltage exceeding the threshold value is applied to the gate electrode 23, a channel is formed in the region around the gate insulating layer 23a in the first semiconductor layer 11. This allows current to flow between the source electrode 21 and the drain electrode 22.

In the manufacturing method of the semiconductor device 140, after performing the steps shown in FIG. 2B to form the third semiconductor layer 13, a part of the second semiconductor layer 12 and a part of the first semiconductor layer 11 are removed; and a trench is formed. The semiconductor device 140 is manufactured by forming the gate insulating layer 23a and the gate electrode 23 inside the trench.

In any of the semiconductor devices 110, 120, 130, or 140 described above, the occurrence of current collapse can be suppressed by providing the third semiconductor layer 13.

Embodiments of the present invention include the following features.

### (Feature 1)

A semiconductor device, comprising:
a first semiconductor layer containing Alₓ₁Ga₁₋ₓ₁N (0≤x1<1);
a second semiconductor layer provided on the first semiconductor layer and containing Alₓ₂Ga₁₋ₓ₂N (0<x2<1, x1<x2), the second semiconductor layer including a first portion and a second portion, the second portion being separated from the first portion in a second direction perpendicular to a first direction from the first semiconductor layer toward the second semiconductor layer;
a first electrode provided on the first portion;
a second electrode provided on the second portion;
a gate electrode provided between the first electrode and the second electrode;
a third semiconductor layer located between the gate electrode and the second electrode and containing carbon and gallium nitride, a concentration of carbon in the third semiconductor layer being greater than 5.0×10¹⁷ cm⁻³.

### (Feature 2)

The semiconductor device according to feature 1, wherein
the third semiconductor layer is separated from the gate electrode in the second direction.

### (Feature 3)

The semiconductor device according to feature 1 or 2, wherein
a distance in the second direction between the gate electrode and the third semiconductor layer is not less than 0.5 times a distance in the second direction between the gate electrode and the second electrode.

### (Feature 4)

The semiconductor device according to any one of features 1 to 3, wherein
the third semiconductor layer is of p-type.

### (Feature 5)

The semiconductor device according to any one of features 1 to 4, wherein
the third semiconductor layer is in contact with the second electrode.

### (Feature 6)

The semiconductor device according to any one of features 1 to 5, wherein
a part of the second electrode is provided on the third semiconductor layer.

### (Feature 7)

The semiconductor device according to any one of features 1 to 6, wherein
the second semiconductor layer includes a third portion located between the first portion and the second portion,
the gate electrode is located on the third portion and is in contact with the third portion, and
a concentration of fluorine in the third portion is greater than a concentration of fluorine in the first portion and greater than a concentration of fluorine in the second portion.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device, comprising:
a first semiconductor layer containing Alₓ₁Ga₁₋ₓ₁N (0≤x1<1);
a second semiconductor layer provided on the first semiconductor layer and containing Alₓ₂Ga₁₋ₓ₂N (0<x2<1, x1<x2), the second semiconductor layer including a first portion and a second portion, the second portion being separated from the first portion in a second direction perpendicular to a first direction from the first semiconductor layer toward the second semiconductor layer;
a first electrode provided on the first portion;
a second electrode provided on the second portion;
a gate electrode provided between the first electrode and the second electrode;
a third semiconductor layer located between the gate electrode and the second electrode and containing carbon and gallium nitride, a concentration of carbon in the third semiconductor layer being greater than 5.0×10¹⁷ cm⁻³.

2. The semiconductor device according to claim 1, wherein
the third semiconductor layer is separated from the gate electrode in the second direction.

3. The semiconductor device according to claim 1, wherein
a distance in the second direction between the gate electrode and the third semiconductor layer is not less than 0.5 times a distance in the second direction between the gate electrode and the second electrode.

4. The semiconductor device according to claim 1, wherein
the third semiconductor layer is of p-type.

5. The semiconductor device according to claim 1, wherein
the third semiconductor layer is in contact with the second electrode.

6. The semiconductor device according to claim 1, wherein
a part of the second electrode is provided on the third semiconductor layer.

7. The semiconductor device according to claim 1, wherein
the second semiconductor layer includes a third portion located between the first portion and the second portion,
the gate electrode is located on the third portion and is in contact with the third portion, and
a concentration of fluorine in the third portion is greater than a concentration of fluorine in the first portion and greater than a concentration of fluorine in the second portion.
